(19) United States
(12) Patent Application Publication
(10) Pub. No.: US 2010/0151130 A1
(43) Pub. Date: Jun. 17, 2010

(54) COMBUSTION CHEMICAL VAPOR DEPOSITION ON TEMPERATURE-SENSITIVE SUBSTRATES

(75) Inventors: Johannes A.M. Ammerlaan, Eindhoven (NL); Ralph T.H. Maessen, Eindhoven (NL); Roland Weidl, Bollberg (DE)

Correspondence Address: Muncy, Geissler, Olds & Lowe, PLLC, 4000 Legato Road, Suite 310, FAIRFAX, VA, 22033, US

(73) Assignee: KONINKLIJKE PHILIPS ELECTRONICS, N.V., EINDHOVEN (NL)

(21) Appl. No.: 11/720,851

(22) PCT Filed: Dec. 7, 2005
(86) PCT No.: PCT/IB05/54103

§ 371 Date: Oct. 8, 2009

Related U.S. Application Data
(60) Provisional application No. 60/635,245, filed on Dec. 10, 2004.

(51) Int. Cl. C23C 16/453

(52) U.S. Cl. 427/255.28; 118/724

(57) ABSTRACT

Method and apparatus for depositing film on flexible (plastic/metal) foil and/or temperature sensitive substrates (101) by combustion chemical vapor deposition (C-CVD). A substrate (101) is held in place to provide physical and conductive thermal contact between the substrate (101) and a substrate holder (102). The substrate holder (102) is cooled using a cooling fluid and the substrate (101) and burner are moved relative to each other as C-CVD takes place. Heating of the substrate (101) during C-CVD is controlled and deterioration by heating is avoided. The foil or substrate (101) is suitable, in particular, for use in flat and flexible displays.

A related application Ser. No. ______ (applicants' assignee's docket no. US040541) is filed contemporaneously with this application.

The invention relates to deposition of a thin film on a substrate by a process of combustion chemical vapor deposition.

Combustion chemical vapor deposition (C-CVD) is a relatively new technique for gas phase deposition of films and coatings on a substrate at atmospheric pressure. In C-CVD, gaseous chemical reactants (“precursors”) are activated in a combustion flame before they reach the substrate surface. As a result, the substrate temperature may be significantly lower in C-CVD than in conventional (thermal) CVD processes, where only the substrates are heated. The combination of atmospheric pressure (“open air”) and low temperature processing make C-CVD a promising technique for various applications in which high throughput coating is required, with inexpensive equipment, on temperature-sensitive substrates.

A number of publications on the C-CVD technique have appeared in the literature. For example, “Combustion chemical vapor deposition: A novel thin-film deposition technique,” A. T. Hunt et al., Applied Physics Letters 63 (1993) 266-268 discloses a C-CVD technique in which a flame provides an environment for deposition of a dense film, elemental constituents of which are derived from solution, vapor or gas sources. A number of patents on C-CVD techniques have issued (e.g., U.S. Pat. No. 5,652,021 (1997) corresponding to WO 94/21841). The prior art discloses that a number of different materials can be deposited on various types of substrate materials such as ceramics, glass, metals, and polymers. Although many applications are being envisaged, no current industrial applications are known and it is believed that C-CVD is still at a development stage.

Several methods for maintaining substrates at deposition temperatures that are desirable for certain processes have been reported in the art. See, for example, US 2003/0113479 A1 in which, in a treatment process with a plasma at atmospheric pressure, the temperature of a ground electrode surface of metal base material (substrate) is controlled by supply of chilled water to the interior of the ground electrode.

U.S. Pat. No. 5,135,730 to Suzuki et al. discloses a process to synthesize diamond by combustion in which a flame contacts a surface of a substrate with a temperature maintained from 300° C. to 1200° C. by cooling water flow through a substrate holder, by cooling water and air flow through a substrate holder or by cooling gas directed against the back of the substrate.

In a plasma jet deposition process a substrate may be mounted on a cooling block with a gap between the substrate and a surface of the cooling block being filled with a gas to improve heat transfer, as disclosed in published European application no. EP 0747505A2.

U.S. Pat. No. 5,085,904 to Deak et al. discloses multi-layer structures suitable for food packaging in which barrier layers of SiO and SiO₂ are successively vacuum deposited on a polyester or polyamide resin substrate such as polyethylene terephthalate (PET) film.

A flexible display can be achieved by a structure in which thin film transistors (TFT's) are formed on a flexible substrate, in particular a polymer substrate, as components of display elements or pixels of an active matrix. These structures typically comprise several layers, including semiconductor, dielectric, electro-conductive and barrier layers.

The combustion flame in C-CVD must, in general, be in close proximity to the substrate. As a result, heating-up of the substrates by the flame may be a serious problem, especially if the substrates (e.g. polymers) are sensitive to high temperature. The methods to prevent excessive heating of substrates, which are described in the literature, are rather inefficient. The prior art includes blowing of cold air on the back of the substrate, and/or moving (“sweeping”) the burner over the substrate surface, and cooling a substrate holder by air or water flow or by moving the substrate past the flame. Otherwise, no special arrangements are disclosed in the existing publications on C-CVD to prevent excessive heating up of substrates. Many plastic substrates, especially foils, deteriorate if subjected to conventional procedures, making them unsuitable for some applications, such as processing of flexible foils to be used in displays.

A solution for the above limitations has been found by moving the substrate and burner relative to each other while maintaining conductive heat transfer between a susceptor (a substrate support plate or holder) and a foil to be coated and maintaining the susceptor temperature.

Accordingly, it is desirable to provide a C-CVD apparatus and method for deposition of a thin film on a temperature sensitive substrate.

It is also desirable to provide an apparatus for controlling the distribution of heat to a substrate during deposition of a thin film by C-CVD.

It is further desirable to provide a method and apparatus for combustion chemical vapor deposition of a dense barrier film on a temperature sensitive substrate.

The substrate temperature should be at least 50° C., preferably above 70° C. to prevent condensation of water generated by the combustion flame, and below the temperature at which the substrate deteriorates, typically, for a polymer foil, the glass transition temperature of the polymer, which depends on the type of material.

One application of the apparatus and method of the present invention is in manufacturing of flat, flexible displays. Silica (SiO₂) layers deposited on a substrate by C-CVD may, in particular, serve as barrier layers and/or dielectric layers. Barrier layers are layers which are required to prevent permeation of oxygen and moisture. The C-CVD silica layer may be part of a multilayer stack, with other inorganic and/or organic layers.

In one embodiment the present invention concerns a C-CVD technique for deposition of films on flexible (plastic/metal foil) and/or temperature sensitive substrates specifically for display technologies.

These and other aspects of the invention will be apparent from and elucidated with reference to the embodiment(s) described hereinafter.

An embodiment of the invention will be described, by way of example only, with reference to the drawings, in which:

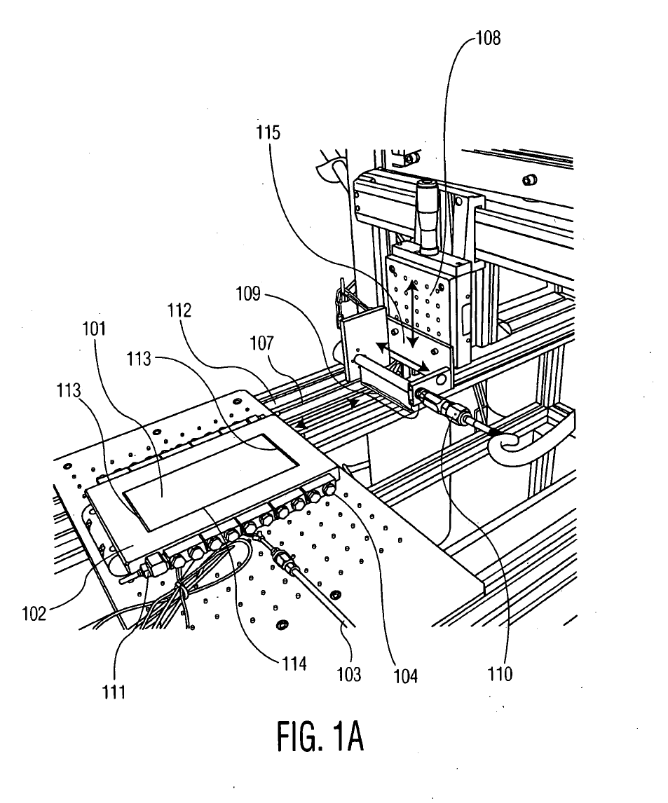

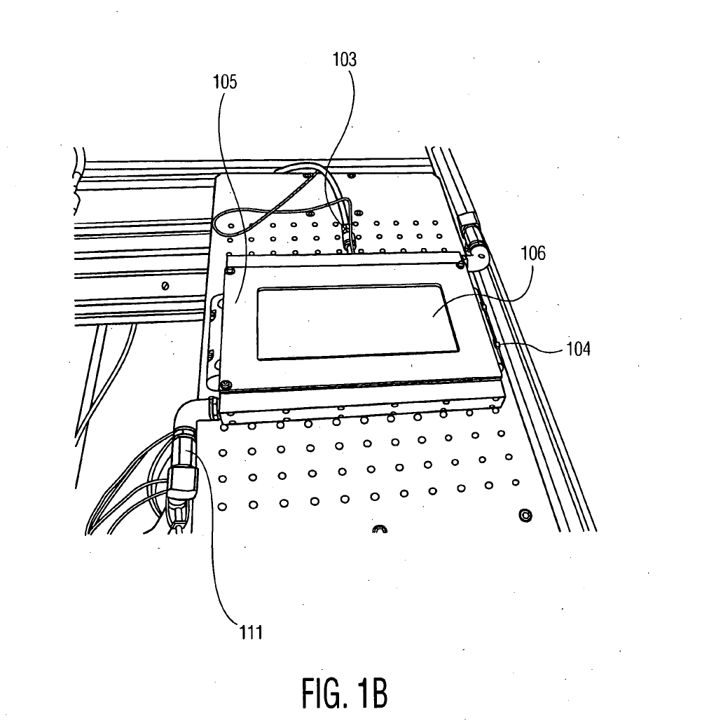

FIG. 1a shows an exemplary embodiment of a combustion chemical vapor deposition apparatus of the present invention.

FIG. 1b shows a second view of the combustion chemical vapor deposition apparatus of FIG. 1a.

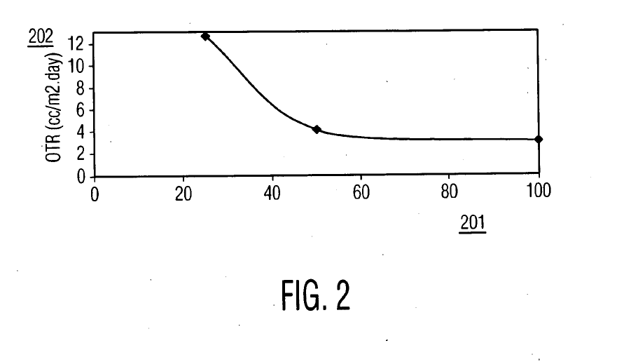

FIG. 2 is a graph showing a relation between coating thickness and oxygen transmission rate (OTR) on a polymer substrate.

Referring to FIG. 1a, in one embodiment of the present invention, substrate 101, e.g. a piece of flexible polymer or metal foil, or a sheet of glass, is kept on a substrate holder 102 by means of suction (connected to a vacuum line 103). The substrate holder 102 has a coolant inlet 111 and coolant outlet 112 and contains channels 104 for temperature control using water from a heater/cooler circulator (not shown).

In this embodiment, the vacuum line 103 is connected to vacuum channels (not shown) in the substrate holder 102 which connect to vacuum openings 113 on a surface of the substrate holder. The vacuum openings 113 are in a rectangular groove 114 which extends around and is outside the periphery of a frame opening 106 (shown in FIG. 2).

An aluminum frame 105 is placed on top of the substrate 101 and holder in order to protect the edges of the flexible substrates. The coated area on the substrate 101 corresponds to the frame opening 106. The substrate holder 102 is mounted for linear movement (in an x-direction along an axis 107). The C-CVD burner holder is height adjustable, and mounted for linear movement (in a z-direction, i.e. perpendicular to substrate 101 movement, along an axis 108), in order to achieve improved uniformity. In other embodiments, the burner 109 may be movable in a y-direction along an axis 115 perpendicular to axes 107 and 108. The burner 109 position is typically 10-20 mm from the substrate 101 and may be controlled by a control system (not shown). The control system may, for example, include a microprocessor and data storage device, temperature sensor, program of instructions, and a device capable of positioning the burner in accordance with a signal generated by the program of instructions, from the temperature sensed, to maintain a desired temperature. Control systems of this kind are well known to those of ordinary skill in the art.

Alternatively, the control system may cause the substrate holder 102 to be moved to a position with respect to the burner 109 in order to maintain a desired temperature of the substrate 101

The burner 109 has a linear shape, and is fed with a gas feed 110 of a common combustible gas such as propane or natural gas, and an oxidizing gas such as pure oxygen or air. The burner 109 gases may be pre-mixed or surface-mixing. Nitrogen may be added to adjust the temperature and shape of the flame. Part of the nitrogen flow may be passed through a so-called bubbler, in which it is saturated with the vapor of coating precursor, for example, tetra-ethoxy-silane (TEOS). Alternatively, TEOS or another precursor may be mixed with nitrogen, an inert gas or the oxidizing gas using a mixing valve, nebulizer, aspirator or similar device. TMOS (tetramethylorthosilicate) and HMDSO (hexamethyldisiloxane), for example, as well as TEOS, are common CVD precursors for silica coatings in conventional (thermal) CVD processes and may also be used in the present invention. Other metal oxide materials such as lanthanum oxide, chromium oxide, tungsten oxide, molybdenum oxide, vanadium oxide, and copper oxide may be used.

In this embodiment, the TEOS concentration is 0.01-0.05 mol % in the total gas stream (i.e. the mixture of combustion gas, oxidant gas, inert carrier/diluent gas and precursor gas). Substrate temperature is kept about 70° C. The substrate velocity as it is drawn through the burner 109 along the x-direction axis 107 is 30-200 mm per second. The distance along the axis 108 (z-direction) from the burner 109 to-the substrate 101 is maintained at 10 mm. A deposition rate of 1-20 nm per pass is achieved. The number of passes determines the final thickness of the coating.

A substrate temperature of at least 50° C., and preferably above 70° C. prevents condensation of water generated by the combustion flame. Condensation of water prevents the growth of a continuous coating. Condensation generated by the combustion flame is affected by, among other things, the amount of nitrogen or other non-oxidizing gas used to dilute the feed to the burner, with a higher amount of diluent allowing a lower substrate temperature.

The upper limit of the substrate temperature depends on the type of substrate material, rather than being determined by the C-CVD process. For polymer substrates the upper limit depends on, among other factors, the glass transition temperature (Tg) of the polymer material and is, typically, lower (in the range 80-200° C.) than for, for example, glass (to 600° C.) or metal substrates. Substrates such as polynorbornene (T_{g} of 340° C.), polyimide (275° C.), polyethersulphone (220° C.), polyarylate (215° C.), high temperature polycarbonate (205° C.), polycarbonate (150° C.), polyethylenenapthalate (120° C.) and PET (68° C.) are advantageously used in the present invention. The film material itself may be more stable than the substrates, typically to at least 1000° C.

In this example, SiO₂ coatings have been deposited using C-CVD on sheets of AryLite™, a polyarylate (PAR) substrate for flexible displays manufactured by the company Ferrania S.p.A. The substrate may, however, be of any suitable material. Polymeric materials suitable for use as substrates include, but are not limited to, polycarbonate (PC), polyethersulfone (PES), polynorbonene (PNB), PET, polyethylenenapthalate (PEN), epoxide, polymethylmethacrylate (PMMA), polyurethane (PUR), polyethylene (PE), polypropylene (PP) and polyimide (PI). Different materials may be suited for different uses and are known to those skilled in the art. The substrate may be of an organic compound, or an at least partly inorganic compound arranged with a organic surface. Other substrates that can be used are glass or metal (foils) with or without device structures, that require a barrier coating or dielectric coating.

The apparatus and method of the present invention allow deposition of a film with good properties for a barrier layer in a flexible display screen, in particular, a clear, flexible and dense film of silica (one that has a bulk density that is close to the bulk density of quartz) can be obtained.

The barrier properties of coatings of various thicknesses obtained in this embodiment of the present invention have been determined using standard oxygen permeation (Mocon test) measurements conducted at Dow Corning Plasma Solutions. Table 1 shows the variation of Oxygen Transmission Rate (OTR) with coating thickness for the different samples. There is a significant improvement in OTR for the coated films relative to the uncoated. As the coating thickness increases, the barrier performance is improved. The results are displayed graphically in FIG. 2. In FIG. 2 the x-coordinate 201 is coating thickness, and the y-coordinate 202 is OTR.

TABLE 1
Measured OTR for Coated and Uncoated Samples

| | coating thickness | OTR |
|---|---|---|
| Sample | (nm) | cc/(m² · day) |
| 1. | 100 | 3.03 |
| 2. | 50 | 4.13 |
| 3. | 25 | 12.8 |
| Uncoated | 0 | 3766 |

In another embodiment of the present invention, the same properties are achieved by using a nebulizer to create micron-sized TEOS droplets which are introduced into the flame.

If a polymer substrate is used, it may be flexible. Some of the polymeric test substrates, that may be used in the present invention are described in the article “Flexible active-matrix displays and shift registers based on solution-processed organic semiconductors,” G. H. Gelinck et al, Nature Materials, 2004, 3(2), pages 106 to 110, which is incorporated herein by reference. Such substrates may comprise a support with a foil on top, then a planarisation layer, structured gold as gate electrode, a polymer such as the commercially available epoxy based negative resist SU8 as a gate dielectric, typically SU8 and gold source and drain electrodes.

Because of its precursors are easily and inexpensively produced and applied, silica is advantageously used to form barrier layers. Other materials, including, but not limited to inorganic metal oxides of magnesium, zinc or zirconium, may also be suitable, in particular, as barrier layers, depending on the application.

The invention is not limited to barrier and dielectric layers, but may advantageously be used for other layers, including, without limitation, conducting layers such as a transparent conducting layer of, e.g. indium-tin-oxide (ITO) or doped zinc oxide. Deposition of Al-doped zinc oxide by C-CVD for solar cell applications is known from the prior art.

Finally, the above-discussion is intended to be merely illustrative of the present invention and should not be construed as limiting the appended claims to any particular embodiment or group of embodiments. Each of the systems utilized may also be utilized in conjunction with further systems. Thus, while the present invention has been described in particular detail with reference to specific exemplary embodiments thereof, it should also be appreciated that numerous modifications and changes may be made thereto without departing from the broader and intended spirit and scope of the invention as set forth in the claims that follow. The specification and drawings are accordingly to be regarded in an illustrative manner and are not intended to limit the scope of the appended claims.

In interpreting the appended claims, it should be understood that:
a) the word “comprising” does not exclude the presence of other elements or acts than those listed in a given claim;
b) the word “a” or “an” preceding an element does not exclude the presence of a plurality of such elements;
c) any reference numerals in the claims are for illustration purposes only and do not limit their protective scope;
d) several “means” may be represented by the same item or hardware or software implemented structure or function;
e) any of the disclosed elements may be comprised of hardware portions (e.g., discrete electronic circuitry), software portions (e.g., computer programming), or any combination thereof;
f) hardware portions may be comprised of one or both of analog and digital portions;
g) any of the disclosed devices or portions thereof may be combined together or separated into further portions unless specifically stated otherwise; and
h) no specific sequence of acts is intended to be required unless specifically indicated.

1. A method for applying a material to a substrate (101) comprising:
providing a substrate (101) having a surface;
securing the surface to a substrate holder (102);
maintaining conductive cooling of the substrate (101) through the substrate holder (102); and
positioning the substrate (101) at a distance from a burner (109) to expose the substrate (101) to a reagent mixture in a process of combustion chemical vapor deposition,
said distance being a distance at which temperature of the substrate (101) is at 50 to 600° C. during the combustion chemical vapor deposition process.

2. The method of claim 1, wherein the distance from the burner is about 10-20 mm.

3. The method of claim 2, wherein the distance from the burner (109) is about 10 mm.

4. The method of claim 1, comprising moving the substrate (101) at the distance from the burner.

5. The method of claim 4, wherein moving the substrate (101) at the distance from the burner comprises moving the substrate (101) at a speed of 30-200 mm/second relative to the burner.

6. The method of claim 4 wherein the substrate (101) comprises a polymer and the substrate (101) is maintained at a temperature below 200° C.

7. The method of claim 1, comprising maintaining conductive cooling of the substrate (101) by cooling of the substrate holder (102) and assuring that contact is maintained between the substrate (101) and the substrate holder (102).

7. The method of claim 4 wherein the substrate (101) comprises a polymer and the substrate (101) is maintained at a temperature below 200° C.

8. An apparatus comprising:
a burner capable of delivery of a combustion chemical vapor deposition reagent mixture to a combustion point;
a substrate holder (102);
means for controlling a distance from the combustion point to a substrate (101) held by the substrate holder (102);
means for securing a substrate to the substrate holder (102); and
means for maintaining heat conduction from the substrate (101) through the substrate holder (102).

9. The apparatus of claim 8 comprising means for moving the substrate (101) at the distance from the combustion point.

10. The apparatus of claim 9 wherein the means for moving the substrate (101) comprises means for moving the substrate (101) at a speed of 30-200 mm/second.

11. The apparatus of claim 8 wherein the distance lies within the range of 10-20 mm.

12. The apparatus of claim 11 wherein the distance is about 10 mm.
